(19) United States
(12) Patent Application Publication
(10) Pub. No.: US 2012/0145862 A1
(43) Pub. Date: Jun. 14, 2012

(54) MOUNTING APPARATUS FOR DATA STORAGE DEVICE

(75) Inventors: WEN-TANG PENG, Tu-Cheng (TW); XIN-HU GONG, Shenzhen City (CN); SI-WEN SHU, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 12/982,894

(22) Filed: Dec. 31, 2010

(30) Foreign Application Priority Data
Dec. 9, 2010 (CN) 201010580849.2

(51) Int. Cl. H05K 7/14; F16B 2/20

(52) U.S. Cl. 248/298.1

(57) ABSTRACT

A mounting apparatus for a data storage device includes a bracket, a support member, and a clipping member movably mounted to one end of the support member. The bracket includes two side panels each defining a slide slot and a locking slot. Opposite sides of the support member are slidably mounted in the slide slots. The clipping member includes a fixing block. A moving direction of the clipping member is substantially perpendicular to the sliding direction of the support member. When the support member is slid into the bracket, the fixing block is engaged in the corresponding locking slot. When the clipping member is moved away from the corresponding locking slot, the fixing block is disengaged from the corresponding locking slot. Thereafter, the support member is ready to be drawn out from the bracket.

### BACKGROUND

1. Technical Field

The disclosure relates to a mounting apparatus for data storage devices.

2. Description of Related Art

A bracket is mounted in a computer enclosure, in which a storage device will be attached. However, if there is a data storage device used outside of the computer enclosure, another bracket located outside of the enclosure is needed to accommodate the data storage device, which can be quite inconvenient and costly.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of a mounting apparatus, together with a data storage device.

FIG. 2 is similar to FIG. 1, but viewed from another perspective.

FIG. 3 is an assembled, isometric view of FIG. 1.

FIG. 4 is an assembled, isometric view of FIG. 2.

FIG. 5 is a cross-sectional view of FIG. 4.

FIG. 6 shows another state of use of the mounting apparatus of FIG. 1.

### DETAILED DESCRIPTION

The disclosure, including the accompanying drawings, is illustrated by way of examples and not by way of limitation. It should be noted that references to “an” or “one” embodiment in this disclosure are not necessarily to the same embodiment, and such references mean at least one.

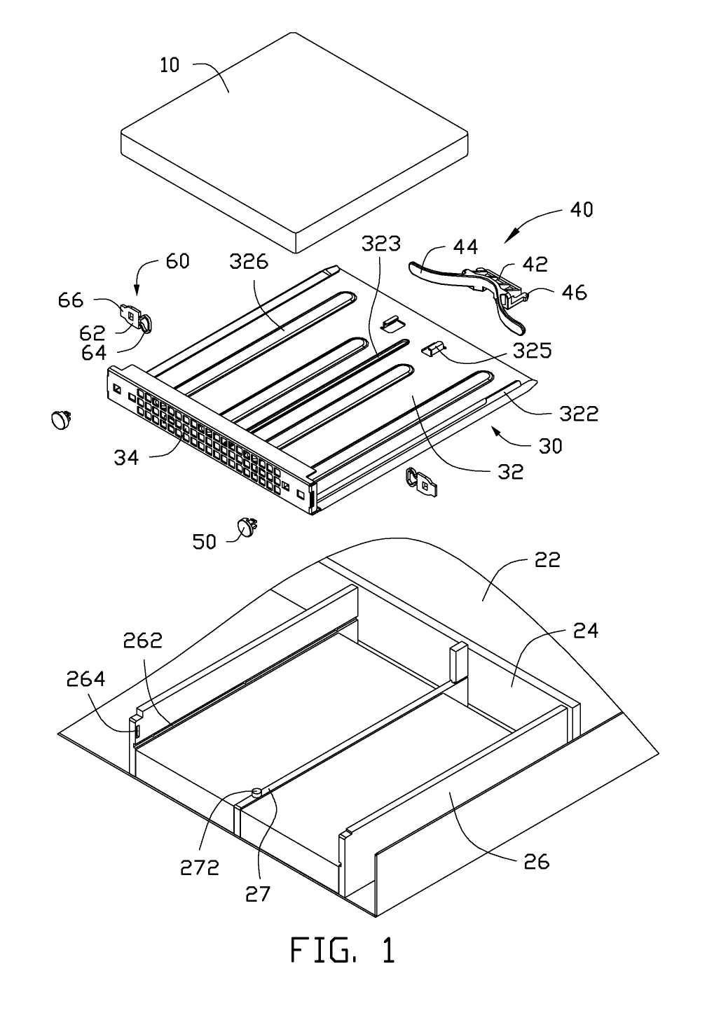

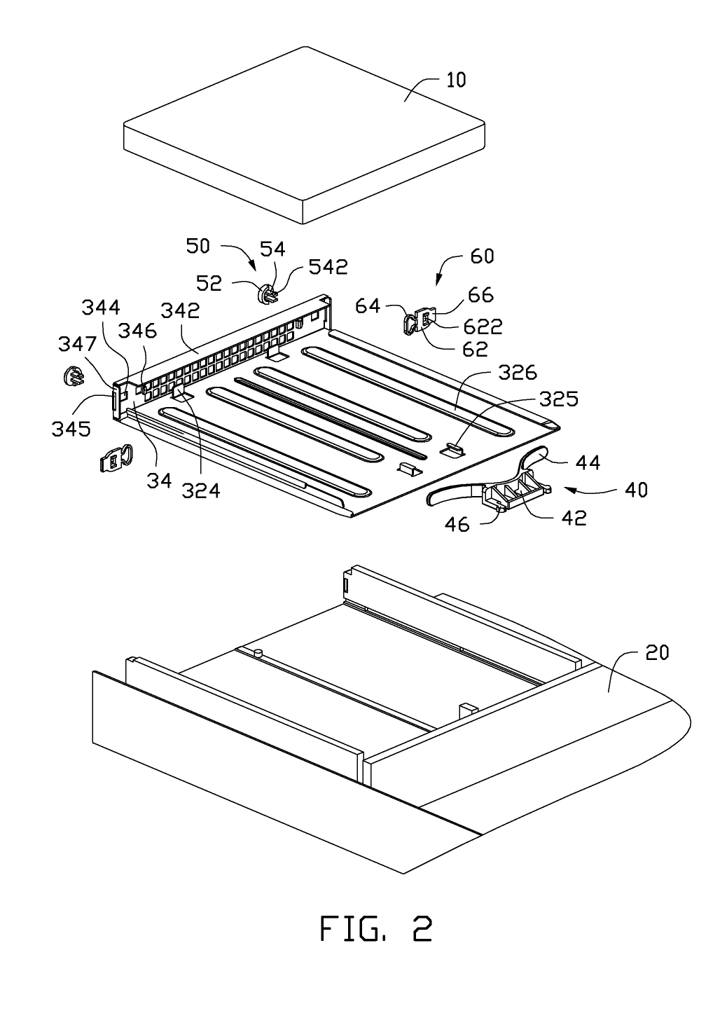

Referring to FIGS. 1 and 2, a mounting apparatus is provided to mount a data storage device 10. The mounting apparatus includes a bracket 20, a support member 30 slidably mounted to the bracket 20, a limiting member 40 mounted to the support member 30, two operation members 50 mounted to the support member 30, and two clipping members 60.

The bracket 20 includes a bottom plate 22, two side panels 26 substantially perpendicularly extending from up opposite sides of the bottom plate 22, and a rear plate 24 substantially perpendicularly extending up from a rear side of the bottom plate 22. The rear plate 24 is substantially perpendicularly connected between rear ends of the side panels 26. An inner side of each side panel 26 longitudinally defines a slide slot 262, parallel to the bottom plate 22. A front end of each side panel 26 defines a locking slot 264, above the corresponding slide slot 262. A truss 27 perpendicularly extends up from the bottom plate 22, between and substantially parallel to the side panels 26. The truss 27 divides a space between the side panels 26 into two receiving spaces, to accommodate data storage devices. A post 272 extends from a top of the truss 27, away from the rear plate 24. In other embodiments, the bracket 20 does not include the rear plate 24.

The support member 30 includes a support board 32 and a mounting board 34 substantially perpendicularly extending up from a front end of the support board 32. Two hems 322 parallel to each other fold up from opposite sides of the support board 32. The support board 32 defines a guiding slot 323 parallel to and between the hems 322. A plurality of protrusions 326 protrudes up from the support board 32, to support the data storage device 10. Two resisting tabs 324 extend up from the support board 32, adjacent to the mounting board 34. Two substantially L-shaped clamping tabs 325 firstly substantially perpendicularly extend up from a rear end of the support board 32, and then extend towards each other. The clamping tabs 325 are opposite to the resisting tabs 324, and are located at opposite sides of the guiding slot 323.

A flange 342 substantially perpendicularly extends rearward from a top of the mounting board 34. Two positioning boards 347 extend rearward from opposite ends of the mounting board 34, perpendicular to the flange 342. Each positioning board 347 defines a through hole 345. The mounting board 34 defines two mounting holes 344 in the ends of the mounting board 34. Two blocks 346 extend rearward from the mounting board 34 between the mounting holes 344, each adjacent to a corresponding mounting hole 344.

The limiting member 40 includes a substantially wedge-shaped main body 42 and two arc-shaped elastic portions 44 extending from opposite ends of a front side of the main body 42. Two elastic hooks 46 extend from opposite ends of the main body 42, away from the elastic portions 44.

Each operation member 50 includes a cylinder-shaped operation portion 52, and two clips 54 extending from the operation portion 52. A protrusion 542 protrudes from a distal end of each clip 54.

Each clipping member 60 includes a main board 62 defining a through hole 622, a fixing block 66 extending from one end of the main board 62, and an elastic resisting portion 64 extending from an opposite end of the main board 62.

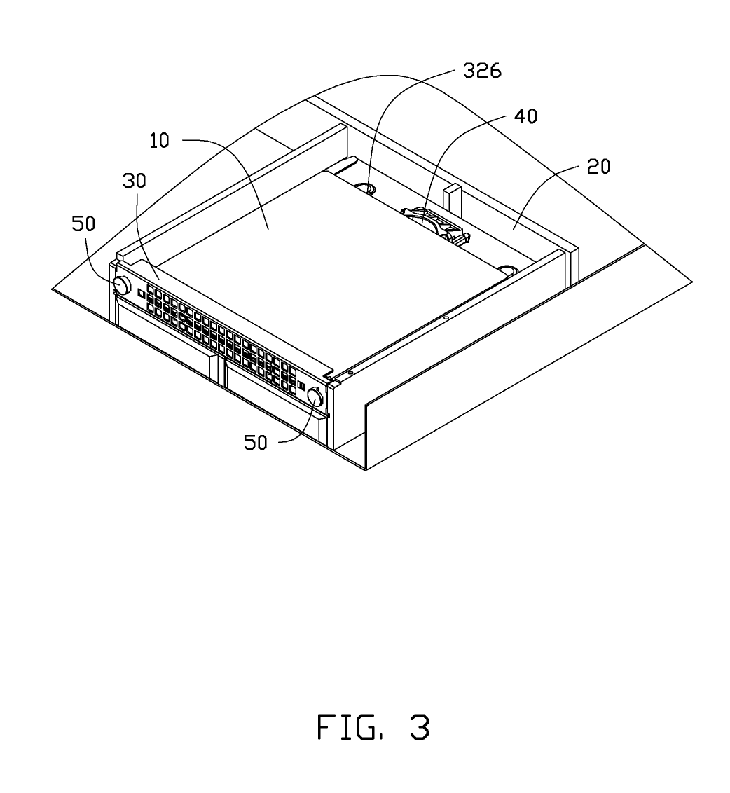

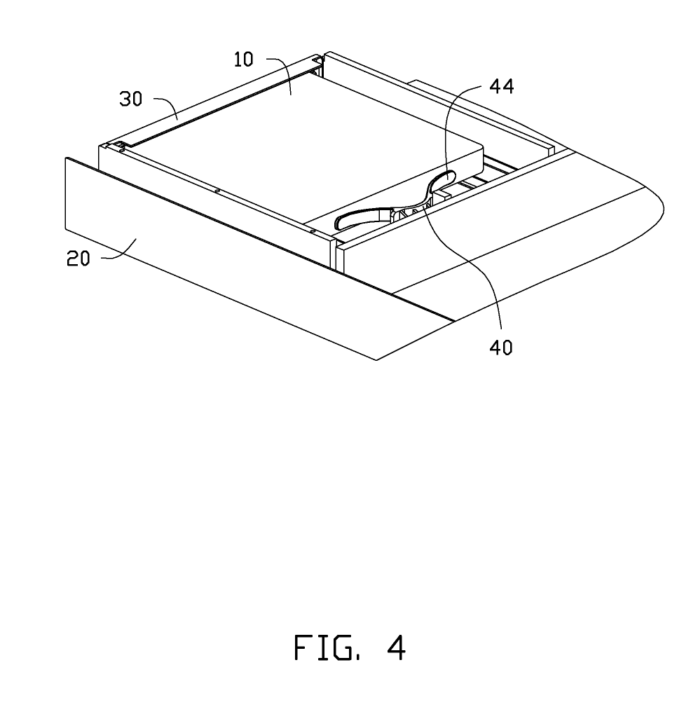

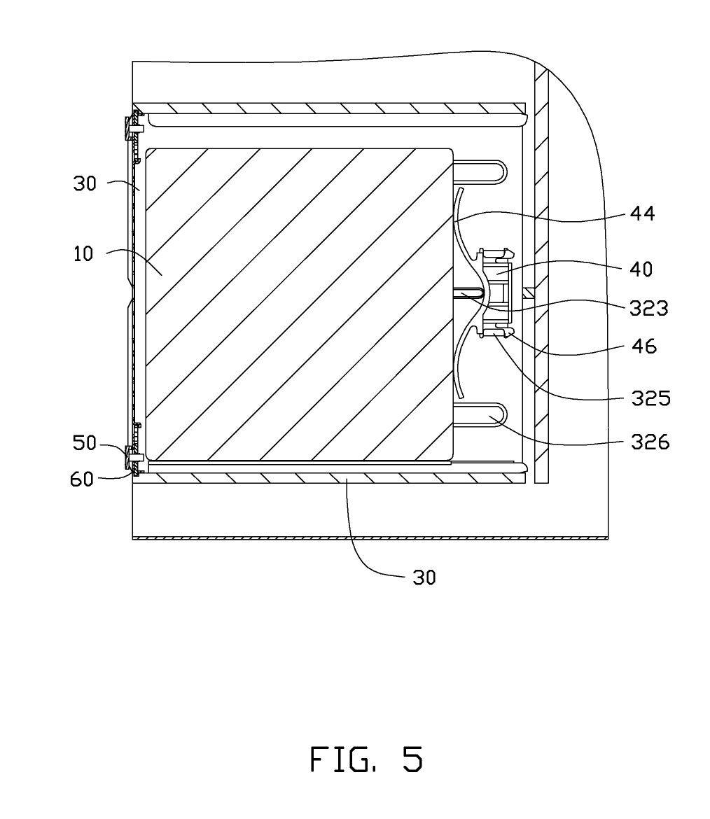

Referring to FIGS. 3 to 5, in assembly, the post 272 of the bracket 20 is extended through the guiding slot 323 of the support member 30. Opposite sides of the support member 30 are slidably engaged in the slide slots 262 of the bracket 20. Therefore, the support member 30 is slidably mounted to the bracket 20. The fixing block 66 of each clipping member 60 is extended through the corresponding through hole 345 of the bracket 20 from an inner side of the bracket 20, and the resisting portion 64 of each clipping member 60 elastically resists against the corresponding block 346. Therefore, each clipping member 60 is mounted to the inner side of the mounting board 34, with the through hole 622 aligned with the corresponding mounting hole 344 of the support member 30. The clips 54 of each operation member 50 are extended through the mounting hole 344 of the support member 30 and the through hole 622 of the clipping member 60, and the protrusions 542 of the clips 54 are blocked by the main board 62 of the clipping member 60. The main body 42 of the limiting member 40 is inserted between the clamping tabs 325, with the elastic hooks 46 of the limiting member 40 blocked by the clamping tabs 325.

In mounting the data storage device 10 in the bracket 20, the data storage device 10 is supported on the protrusions 326 of the support member 30. The front and rear ends of the data storage device 10 resist against the resisting tabs 324 of the support member 30 and the elastic portions 44 of the limiting member 40. Opposite sides of the data storage device 10 abut against the hems 322 of the support member 30. The flange 342 of the support member 30 presses a top of the data storage device 10. Thereafter, the support member 30 together with the data storage device 10 is slid into the bracket 20 along the post 272. In this process, the elastic resisting portions 64 of the clipping members 60 are deformed towards the blocks 346 of the support member 30 by the side panels 26 of the bracket 20 urging the fixing blocks 66 of the clipping members 60. When the fixing blocks 66 are aligned with the locking slots 264 of the bracket 20, the resisting portions 64 are restored, with the fixing blocks 66 engaged in the locking slots 264 of the bracket 20. Therefore, the support member 30 together with the data storage device 10 is received in the bracket 20, and the post 272 resists against an edge bounding the guiding slot 323 of the supporting member 30 adjacent to the mounting board 34.

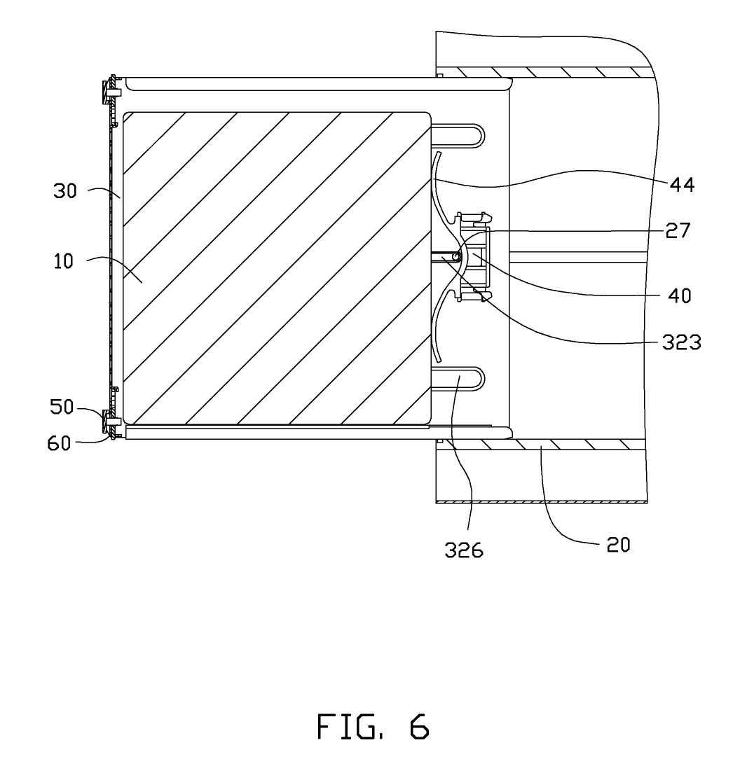

Referring to FIG. 6, if the data storage device 10 is used outside of the bracket 20, the operation portions 52 of the operation members 50 are moved towards each other. Therefore, the fixing blocks 66 of the clipping members 60 are disengaged from the locking slots 264 of the bracket 20, and then, the support member 30 is ready to be drawn out from the bracket 20. In this process, the post 272 is relatively slid in the guiding slot 323, until the post 272 resists against the edge bounding the guiding slot 323 of the supporting member 30 opposite to the mounting board 34. Thereafter, the data storage device 10 can be mounted to the support member 30.

It is believed that the present embodiment and its advantages will be understood from the foregoing description, and it will be apparent that various changes may be made thereto without departing from the spirit and scope of the description or sacrificing all of their material advantages, the example hereinbefore described merely being exemplary embodiment.

1. A mounting apparatus for a data storage device, the mounting apparatus comprising:
a bracket comprising two side panels, each side panel defining an elongated slide slot, and a locking slot adjacent to a front end of the slide slot;
a support member slidably mounted in the slide slots with opposite sides, and accommodating the data storage device; and
a clipping member slidably mounted to a front end of the support member, the clipping member comprising a fixing block, wherein a sliding direction of the clipping member is substantially perpendicular to the sliding direction of the support member, when the support member is slid into the bracket, the fixing block is slidably engaged in a corresponding one of the locking slots, when the clipping member is moved away from the corresponding locking slot, the fixing block is disengaged from the corresponding locking slot, and then, the support member is readily to be drawn out from the bracket.

2. The mounting apparatus of claim 1, wherein the clipping member further comprises an elastic resisting portion opposite to the fixing block, the support member comprises a mounting board at the front end of the support member, and a block extends rearward from the mounting board, the elastic resisting portion elastically resists against the block.

3. The mounting apparatus of claim 2, wherein a positioning board extends rearward from an end of the mounting board, the positioning board defines a through hole, the fixing block extends through the through hole from an inner side of the support member, to selectively engage in or disengage from the corresponding locking slot.

4. The mounting apparatus of claim 3, further comprising an operation member, wherein the mounting board defines a mounting hole, the clipping member defines a through hole aligned with the mounting hole, the operation member comprises two clips extended through the mounting hole of the mounting board to engage in the through hole of the clipping member.

5. The mounting apparatus of claim 4, wherein a protrusion protrudes from a distal end of each clip, to be blocked by the clipping member.

6. The mounting apparatus of claim 2, wherein the support member further comprises a support board substantially perpendicular to the mounting board, opposite sides of the support board are slidably mounted in the slide slots of the bracket, two opposite hems extend from the support board adjacent to the sides to abut against opposite sides of the data storage device.

7. The mounting apparatus of claim 6, wherein a plurality of protrusions protrudes up from the support board, to support the data storage device, a flange extends rearward from the mounting board parallel to the support board, to resist against a top of the data storage device.

8. The mounting apparatus of claim 7, wherein two resisting tabs extend from the support board, adjacent to the mounting board, to resist against a front end of the data storage device.

9. The mounting apparatus of claim 8, further comprising a limiting member, wherein two clamping tabs extend from the support board, away from the mounting board, the limiting member is mounted between the clamping tabs to resist against a rear end of the data storage device.

10. The mounting apparatus of claim 9, wherein the limiting member comprises two elastic hooks clamped to the clamping tabs, and two elastic portions resisting against the rear end of the data storage device.

11. The mounting apparatus of claim 6, wherein the support board defines a guiding slot parallel to the hems, the bracket further comprises a truss between the side panels, a post extends from the truss, the post is sliably extended through the guiding slot.

12. An assembly comprising: a data storage device, and a mounting apparatus to mount the data storage device;
the mounting apparatus comprising:
a bracket comprising two parallel side panels, each side panel defining an elongated slide slot, and a locking slot adjacent to a front end of the slide slot;
a support member comprising a support board, opposite sides of the support board slidably mounted in the slide slots, two resisting tabs extending from a front end of the support board;
a clipping member slidably mounted to a front end of the support member, the clipping member comprising a fixing block; and
a limiting member mounted to the support board, away from the resisting tabs, wherein the data storage device is supported on the support board, with the resisting tabs and the limiting member resisting against front and rear ends of the data storage device, when the support member is slid into the bracket, the fixing block is slidably engaged in a corresponding one of the locking slots, when the clipping member is moved away from the corresponding locking slot, the fixing block is disengaged from the corresponding locking slot, and then, the support member is operable to be drawn out from the bracket.

13. The assembly of claim 12, wherein the support board longitudinally defines a guiding slot, the bracket further comprises a truss between the side panels, a post extends from the truss, the post is slidably extended through the guiding slot.

14. The assembly of claim 13, wherein two substantially L-shaped clamping tabs firstly extend from the support board, and then extend towards each other, the limiting member comprises a substantially wedge-shaped main body and two elastic hooks extending rearward from opposite ends of the main body, the main body is inserted between the clamping tabs, with the elastic hooks blocked by the clamping tabs.

15. The assembly of claim 14, wherein two arc-shaped elastic portions extend from a front side of the main body to resist against a rear end of the data storage device.

16. The assembly of claim 14, wherein the support member further comprises a mounting board perpendicular to the support board, the clipping member further comprises an elastic resisting portion opposite to the fixing block, a block extends from the mounting board, the elastic resisting portion elastically resists against the block.

17. The assembly of claim 16, wherein a positioning board extends from an end of the mounting board, the positioning board defines a through hole, the fixing block extends through the through hole, to engage in or disengage from the locking slot.

18. The assembly of claim 17, wherein the mounting apparatus further comprises an operation member, the mounting board defines a mounting hole, the clipping member defines a through hole aligned with the mounting hole, the operation member comprises two clips extended through the mounting hole of the mounting board and the through hole of the clipping member, and the distal ends of the clips are blocked by the clipping member.
